(19) United States
(12) Patent Application Publication
(10) Pub. No.: US 2025/0234617 A1
(43) Pub. Date: Jul. 17, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Meng-Han CHOU, Hsinchu city (TW); Wei-Ting CHANG, Hsinchu City (TW); Su-Hao LIU, Chiayi County (TW); Chi On CHUI, Hsinchu City (TW); Chien-Hao CHEN, Ilan county (TW)

(21) Appl. No.: 18/661,781

(22) Filed: May 13, 2024

Related U.S. Application Data
(60) Provisional application No. 63/620,289, filed on Jan. 12, 2024.

(51) Int. Cl. H01L 29/417; H01L 21/265; H01L 29/06; H01L 29/423; H01L 29/45; H01L 29/66; H01L 29/775; H01L 29/786

(52) U.S. Cl. CPC H10D 64/251; H01L 21/26586; H10D 30/014; H10D 30/43; H10D 30/6735; H10D 30/6757; H10D 62/121; H10D 62/83; H10D 64/62

(57) ABSTRACT

Embodiments of the present disclosure provide a semiconductor device structure and methods of forming the same. The structure includes a source/drain region disposed over a substrate, an interlayer dielectric layer disposed over the source/drain region, a first conductive feature disposed over the source/drain region, a gate electrode layer disposed over the substrate, and a dielectric layer surrounding the first conductive feature. The dielectric layer includes a first portion disposed between the interlayer dielectric layer and the first conductive feature and a second portion disposed between the first conductive feature and the gate electrode layer, at least a portion of the first portion has a first thickness, and the second portion has a second thickness substantially greater than the first thickness.

### CROSS-REFERENCE TO RELATED APPLICATIONS

This application claims priority to U.S. Provisional Application Ser. No. 63/620,289 filed Jan. 12, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-12A are cross-sectional side views of various stages of manufacturing the semiconductor device structure taken along line A-A of FIG. 6, in accordance with some embodiments.

FIGS. 7B-12B are cross-sectional side views of various stages of manufacturing the semiconductor device structure taken along line B-B of FIG. 6, in accordance with some embodiments.

FIGS. 7C-12C are cross-sectional side views of various stages of manufacturing the semiconductor device structure taken along line C-C of FIG. 6, in accordance with some embodiments.

FIGS. 13A-13G are cross-sectional side views of various stages of manufacturing the semiconductor device structure taken along line C-C of FIG. 6, in accordance with some embodiments.

FIG. 13D-1 illustrates concentration profiles of a species in two source/drain regions of the semiconductor device structure, in accordance with some embodiments.

FIG. 13F-1 is a top view of a dielectric layer of the semiconductor device structure, in accordance with some embodiments.

FIG. 14A-14B are cross-sectional side views of one of various stages of manufacturing the semiconductor device structure taken along lines A-A, C-C of FIG. 6, respectively, in accordance with some embodiments.

FIG. 15A-15B are cross-sectional side views of one of various stages of manufacturing the semiconductor device structure taken along lines A-A, C-C of FIG. 6, respectively, in accordance with some embodiments.

FIGS. 16A-16C are cross-sectional side views of various stages of manufacturing the semiconductor device structure taken along line C-C of FIG. 6, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

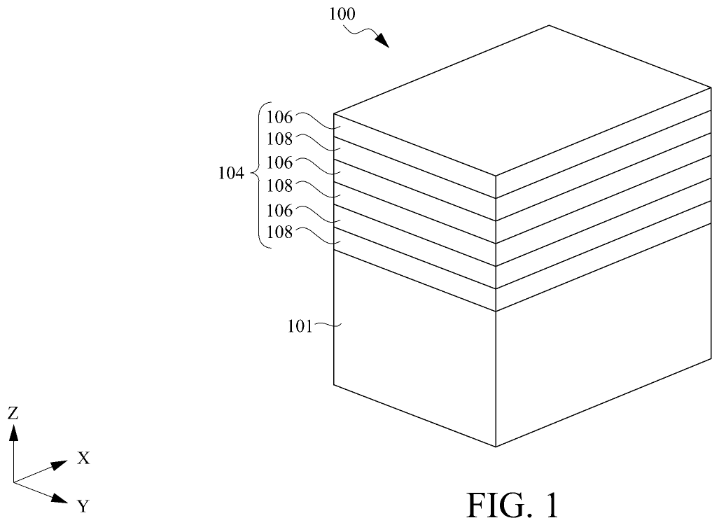

FIGS. 1-15B show exemplary processes for manufacturing a semiconductor device structure 100 according to embodiments of the present disclosure. It is understood that additional operations can be provided before, during, and after processes shown by FIGS. 1-15B, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

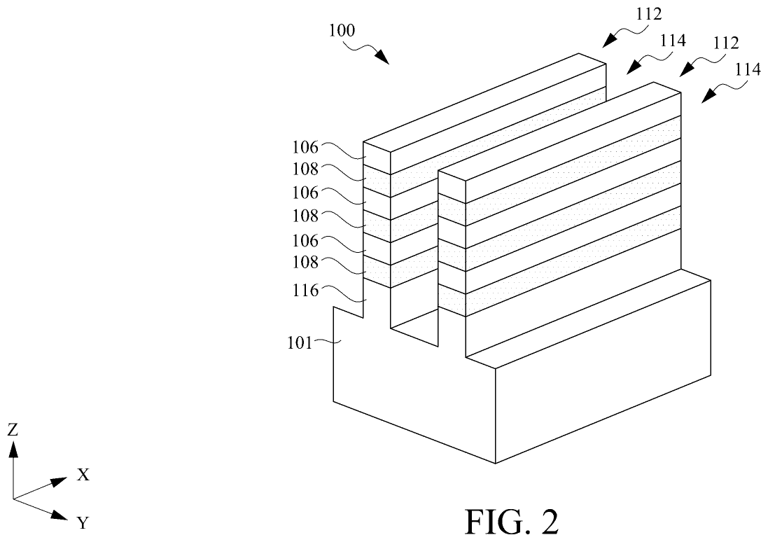

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

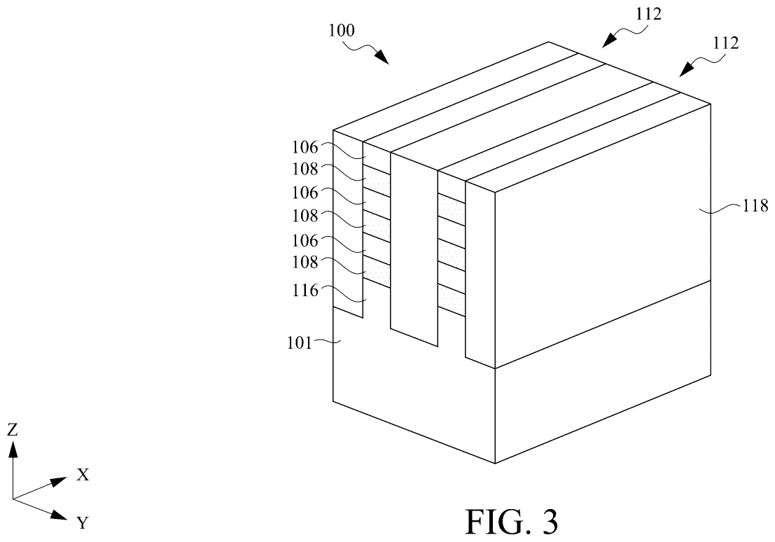

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

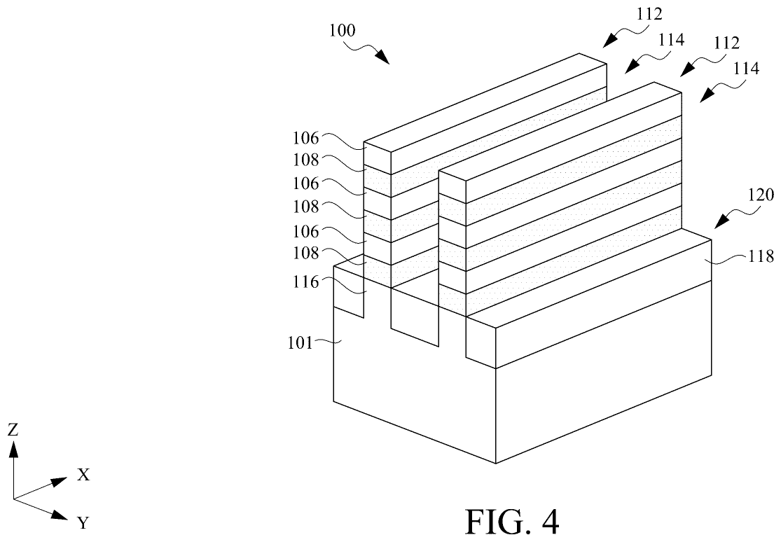

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

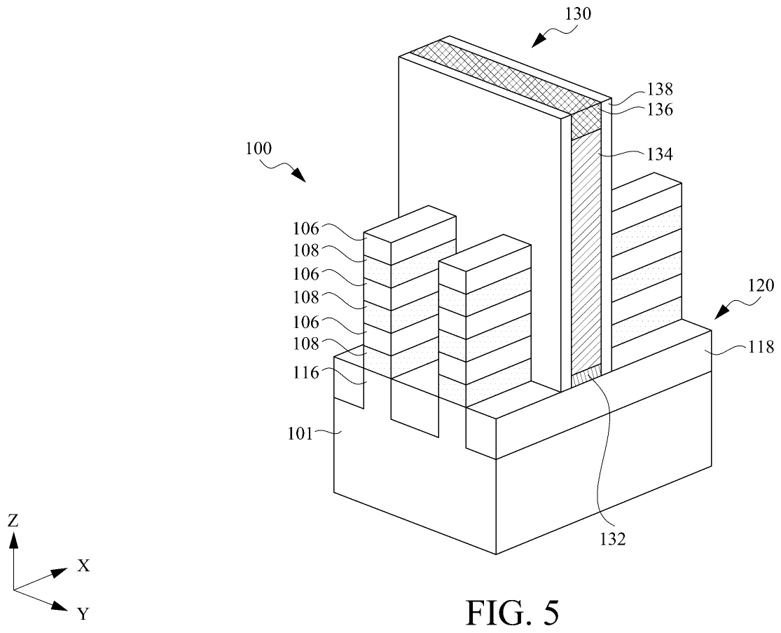

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

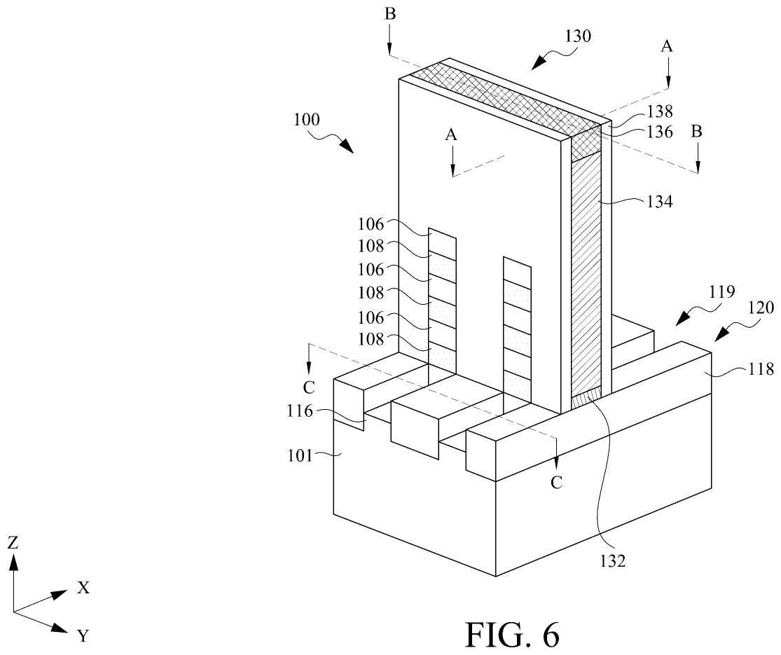

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

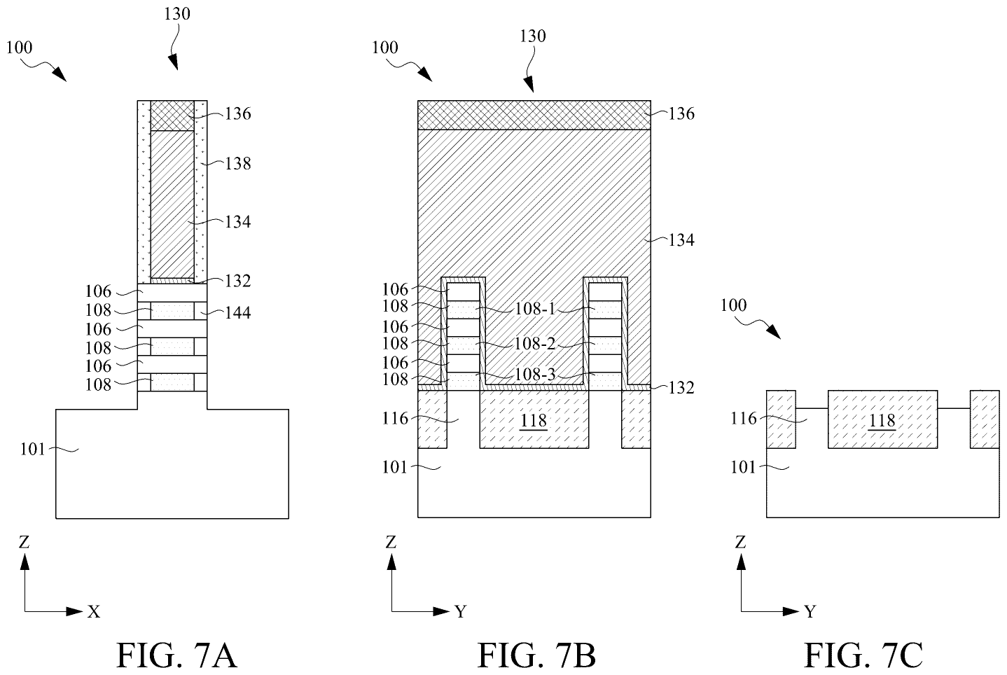

FIGS. 7A, 7B, and 7C are cross-sectional side views of the semiconductor device structure 100 taken along line A-A, line B-B, and line C-C of FIG. 6, respectively.

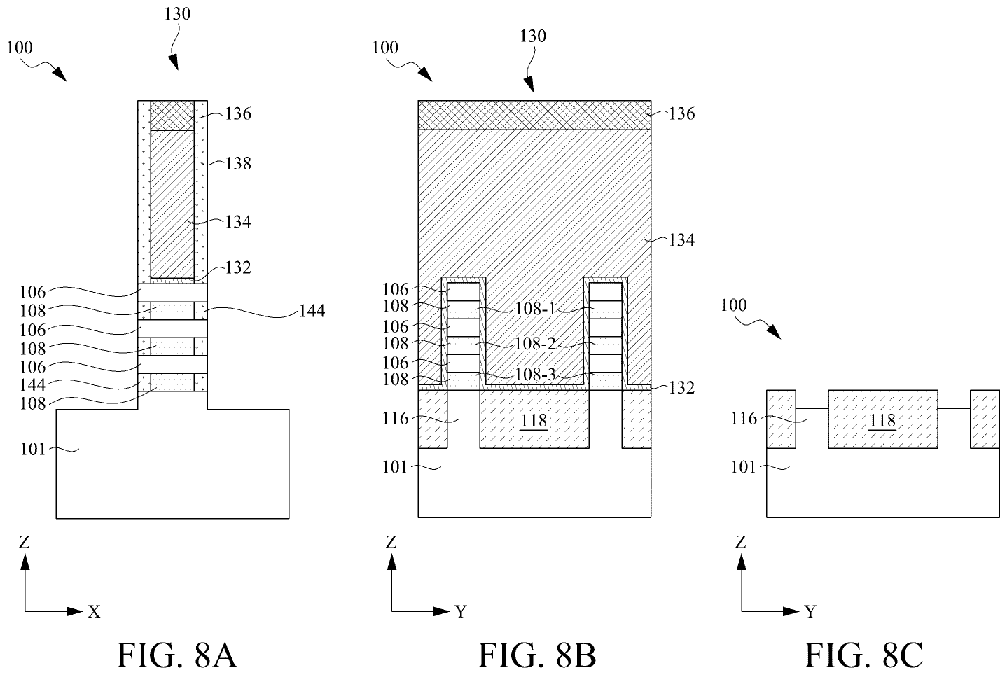

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

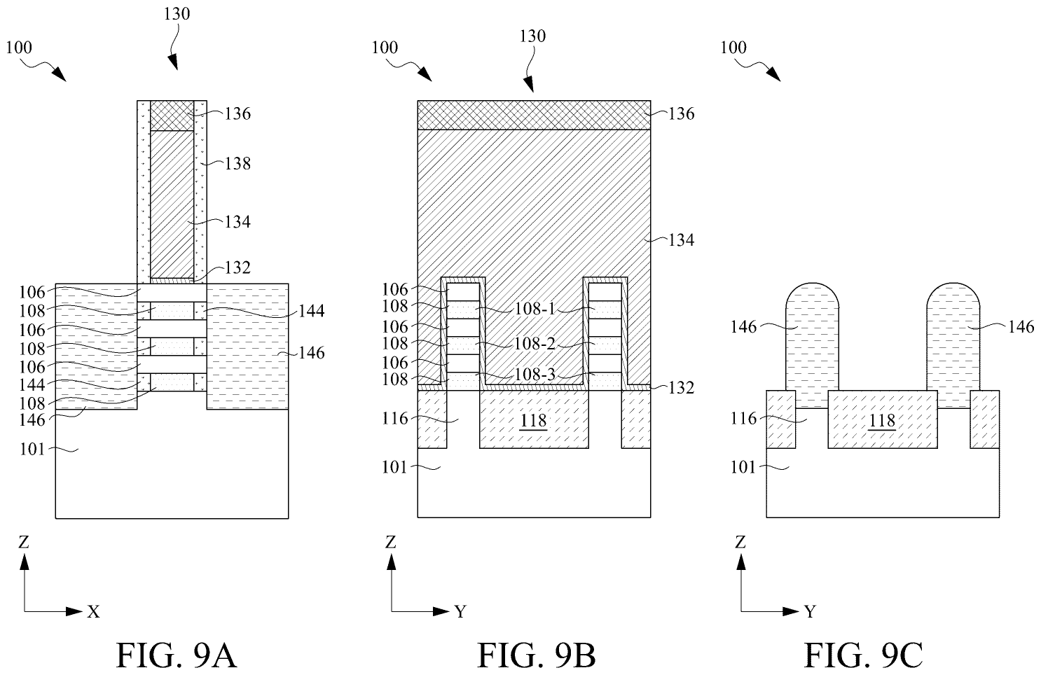

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

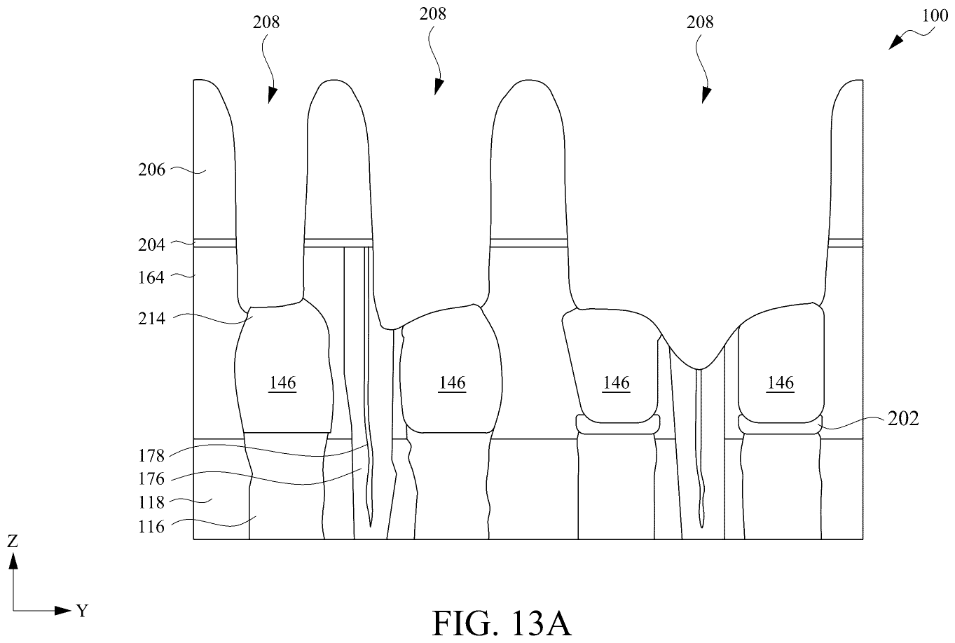

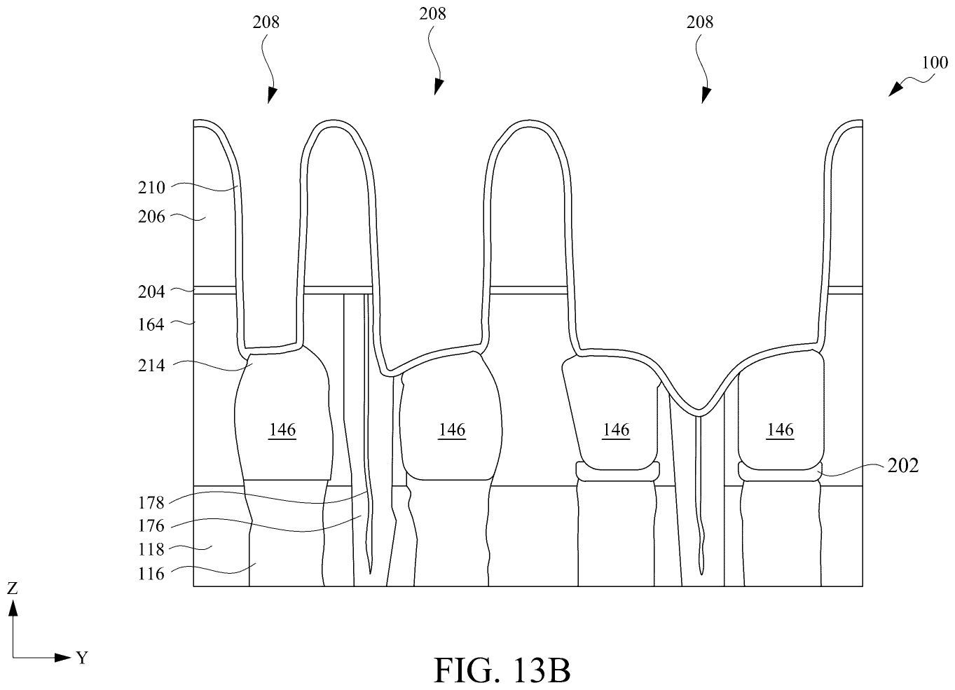

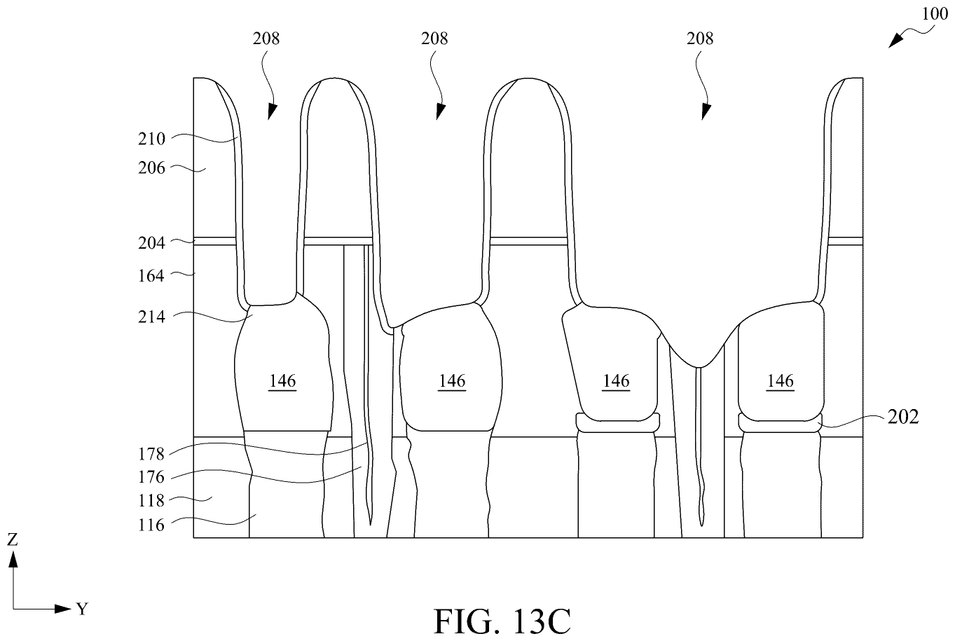

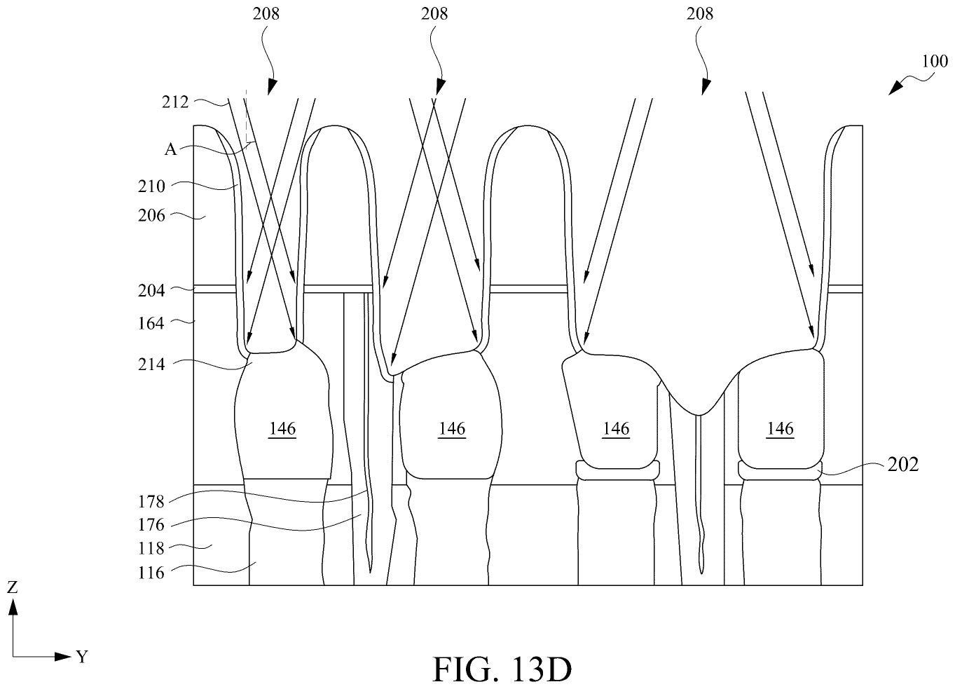

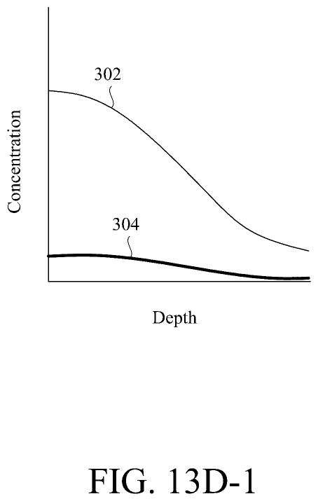

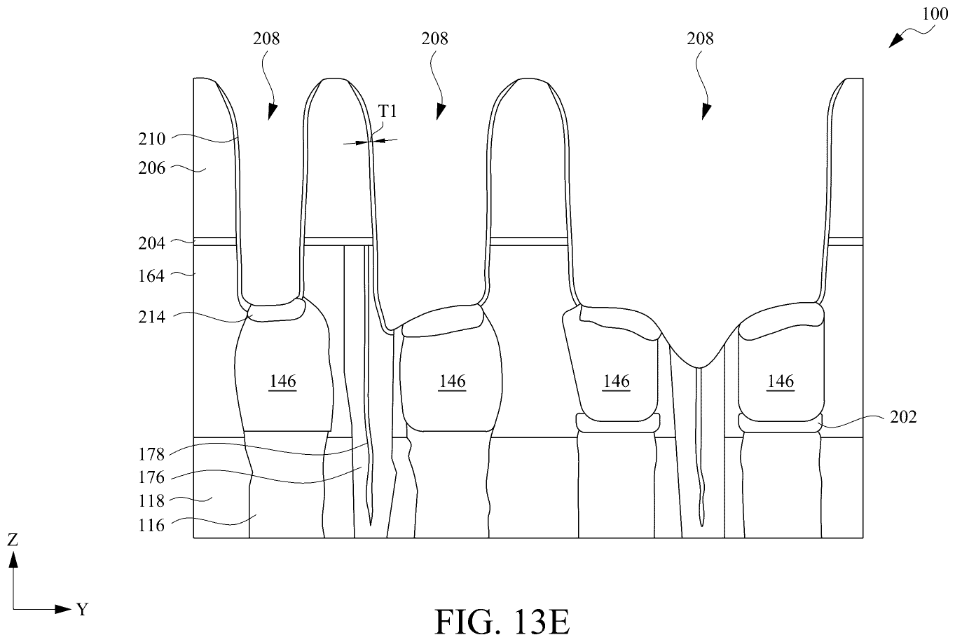

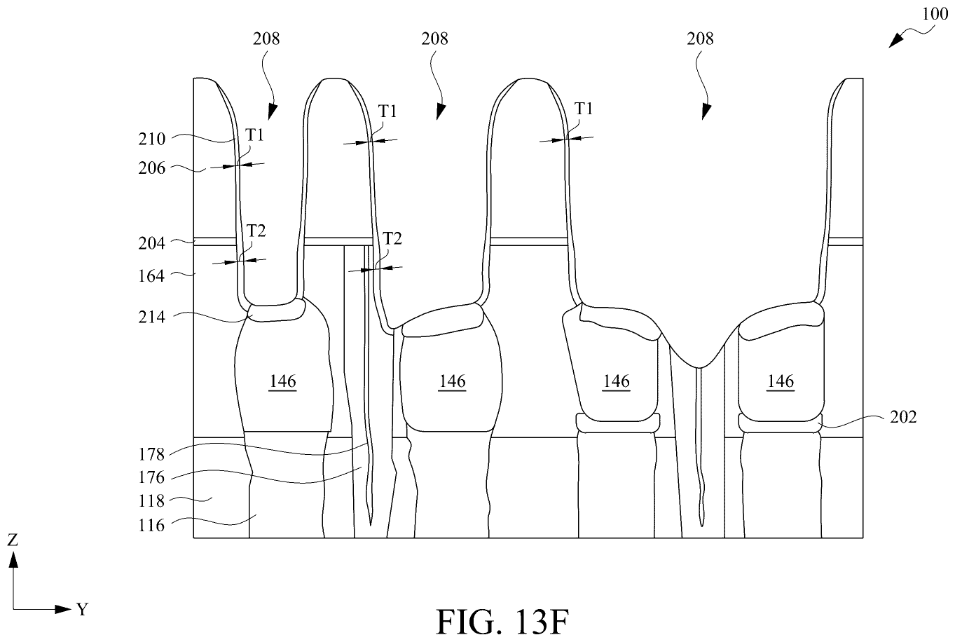

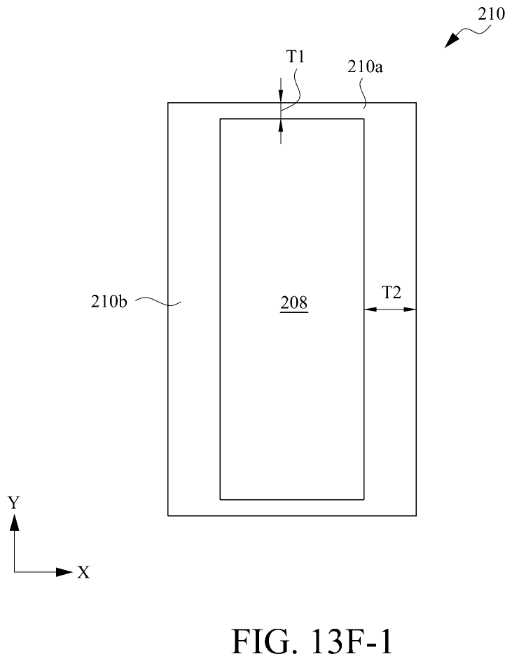

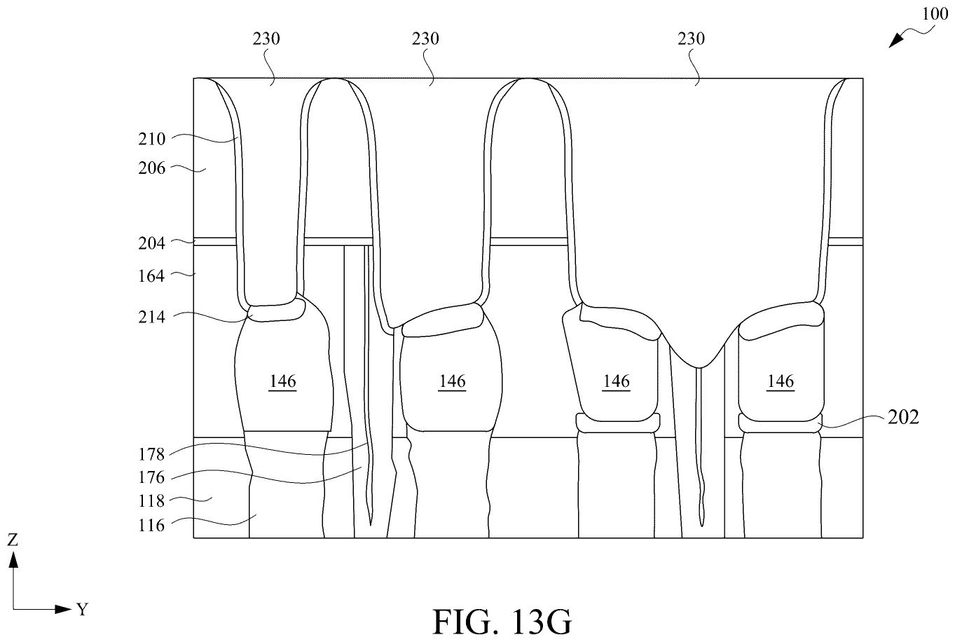

In some embodiments, the S/D region 146 is an n-type epitaxial material, and a dielectric layer 202 (FIG. 13A) may be formed below the S/D region 146. The dielectric layer 202 may prevent current leakage through the substrate portion 116. The dielectric layer 202 may include any suitable dielectric material, such as SiN. The dielectric layer 202 may be formed by first forming a conformal layer on the semiconductor device structure 100, forming a mask on a portion of the conformal layer, and removing exposed portions of the conformal layer. In some embodiments, as shown in FIG. 13A, the dielectric layer 202 is formed under the S/D regions 146 that are n-type epitaxial material and not formed under the S/D regions that are p-type epitaxial material.

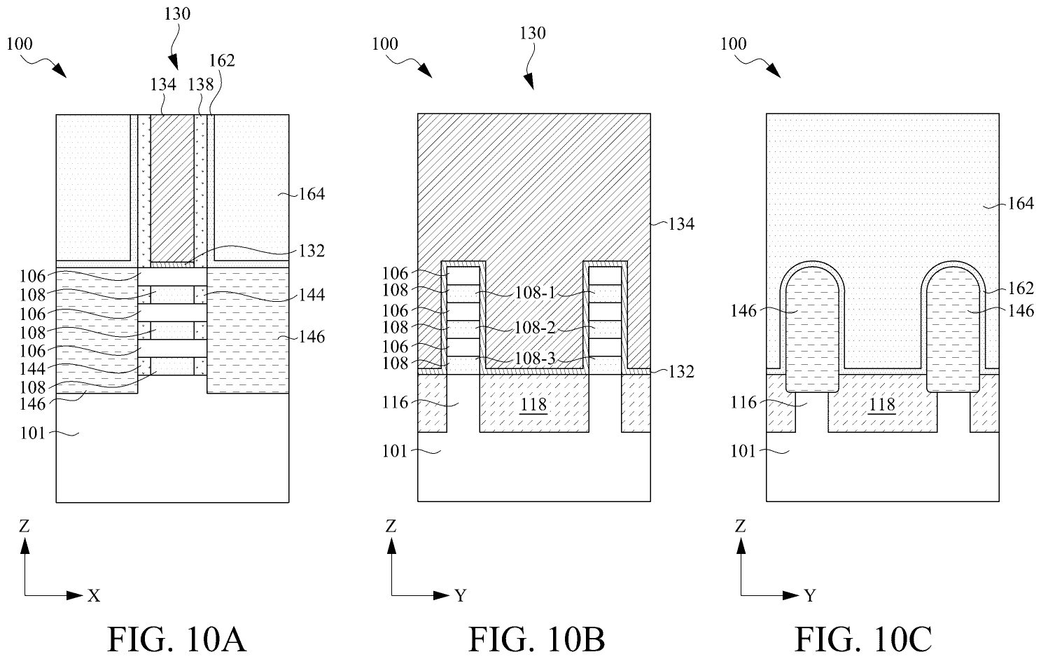

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

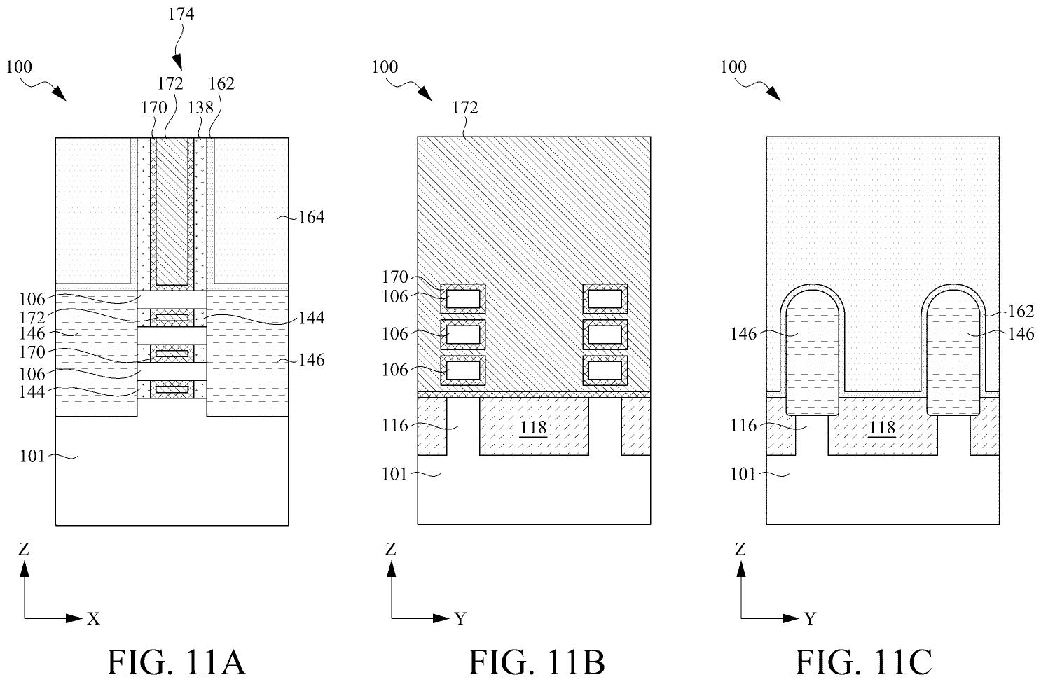

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

Portions of the second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

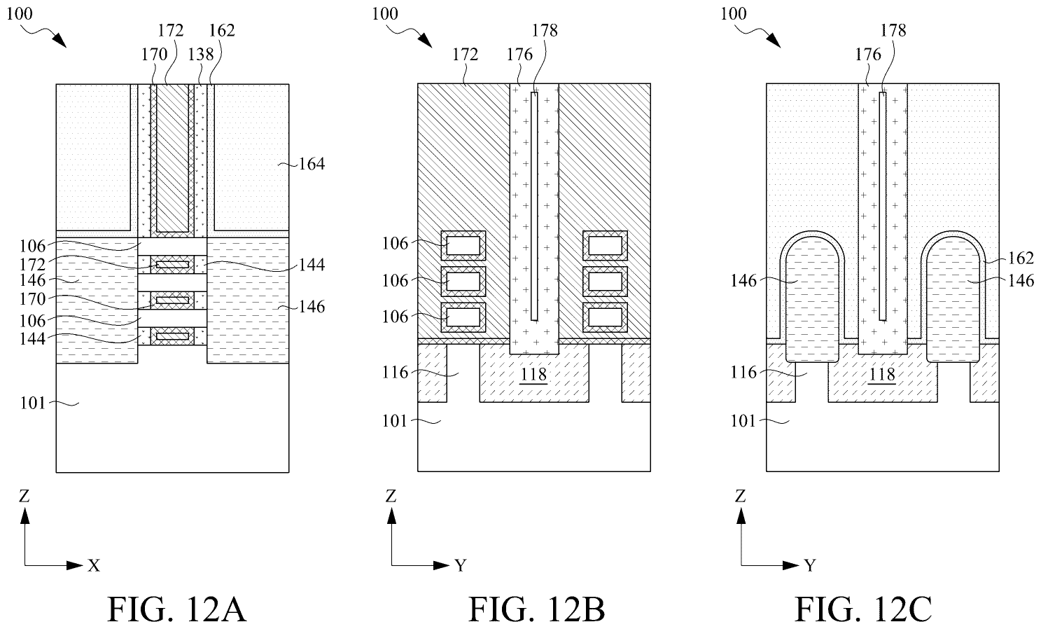

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. As shown in FIGS. 12B and 12C, a cut-metal gate (CMG) process is performed. The CMG process separates the gate electrode layer 172 into multiple segments that can be individually controlled. In some embodiments, an opening is formed in the gate electrode layer 172. The opening may extend to the S/D regions, such as between adjacent S/D regions 146, as shown in FIG. 12C. A dielectric material 176 is formed in the opening. The dielectric material 176 may be any suitable material, such as SiN. In some embodiments, due to the high aspect ratio of the opening, a seam 178 is formed in the dielectric material 176.

FIGS. 13A-13F are cross-sectional side views of various stages of manufacturing the semiconductor device structure 100 taken along line C-C of FIG. 6, in accordance with some embodiments. The CESL 162 is omitted in FIGS. 13A-13F for clarity. As shown in FIG. 13A, an etch stop layer 204 and another ILD layer 206 are formed on the ILD layer 164, the dielectric material 176, and the gate structures 174 (FIG. 12A). The etch stop layer 204 may include the same material as the CESL 162, and the ILD layer 206 may include the same material as the ILD layer 164. Next, openings 208 are formed in the ILD layers 164, 206, the etch stop layer 204, and the CESL 162 to expose the S/D regions 146. In some embodiments, a plurality of openings 208 are formed, some openings 208 each exposes two or more S/D regions 146, while some openings 208 each exposes a single S/D region 146, as shown in FIG. 13A. In some embodiments, two or more S/D regions 146 that are n-type epitaxial material are exposed in a single opening 208, while a single S/D region 146 that is p-type epitaxial material is exposed in an opening 208. The openings 208 may have different sizes (i.e., critical dimensions), such as ranging from about 20 nm to about 30 nm, from about 40 nm to about 60 nm, or greater than 80 nm.

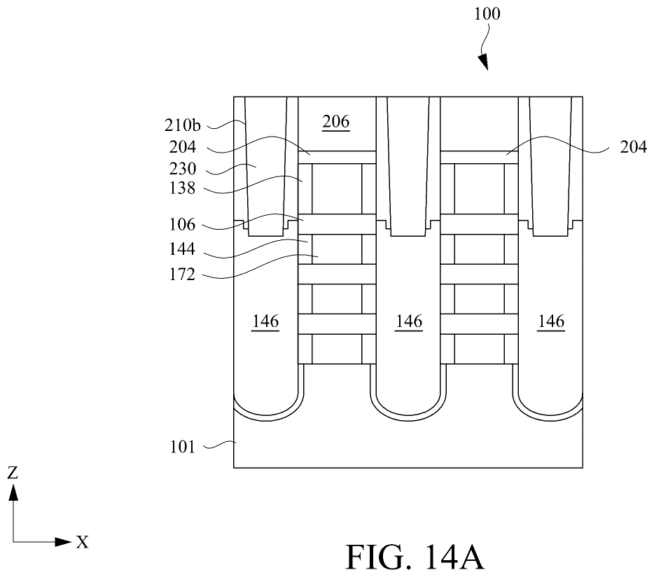

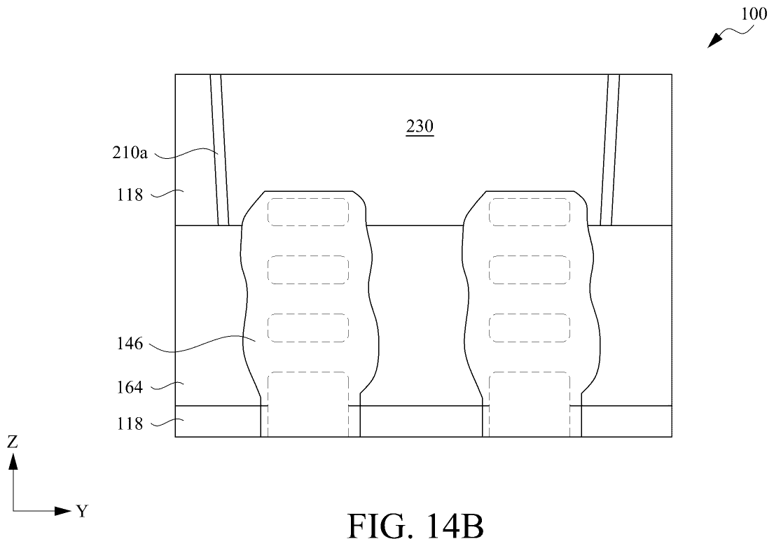

In some embodiments, the portions of the CESL 162 (FIG. 12A) formed on sidewalls of the gate spacers 138 (FIG. 12A) are removed during the formation of the openings 208. In order to improve isolation of the subsequently formed conductive feature (230 FIG. 14a) from the gate electrode layer 172 (FIG. 14a), a dielectric layer 210 is formed in the openings 208, as shown in FIG. 13B. The dielectric layer 210 may include any suitable dielectric material. In some embodiments, the dielectric layer 210 includes SiO₂, SiOC, SiOCN, or SiN. The dielectric layer 210 may be formed by any suitable process. In some embodiments, the dielectric layer 210 is a conformal layer and is formed by ALD. Next, an anisotropic etch process is performed to remove horizontal portions of the dielectric layer 210. After the anisotropic etch process, the dielectric layer 210 is disposed on the sidewalls in the openings 208. The dielectric layer 210 may be formed on the sidewalls of the ILD layers 206, 164, the sidewalls of the etch stop layer 204, and the sidewalls of the CESL 162 in the XZ plane, as shown in FIG. 13C. The dielectric layer 210 may be also formed on the sidewalls of the gate spacers 138, the sidewalls of the ILD layer 206, and the sidewalls of the etch stop layer 204 in the YZ plane, as shown in FIG. 14. The portions of the dielectric layer 210 disposed in the YZ plane is in contact with the gate spacers 138, which is next to the gate electrode layer 172. The portions of the dielectric layer 210 disposed in the XZ plane is not disposed near a conductive material. At the current stage of manufacturing (i.e., after the anisotropic etch process), the thickness of the portions of the dielectric layer 210 disposed in the XZ plane and the thickness of the portions of the dielectric layer 210 disposed in the YZ plane are substantially the same.

As shown in FIG. 13D, an angled implantation process 212 is performed to implant a species into the portions of the dielectric layer 210 disposed in the XZ plane. The angled implantation process 212 implants a species, such as Ge, Xe, Ar, Si, or other suitable species, into the portions of the dielectric layer 210 disposed in the XZ plane, while the portions of the dielectric layer 210 disposed in the YZ plane is substantially not affected by the angled implantation process 212. In some embodiments, the angled implantation process 212 has an implantation energy ranging from about 0.3 keV to about 50 keV, an implantation dosage ranging from about 5E13 atoms/cm² to about 1E16 atoms/cm², and a processing temperature ranging from about −100 degrees Celsius to about 500 degrees Celsius. In order to implant the species into the portions of the dielectric layer 210 disposed in the XZ plane while avoiding implanting the species into the portions of the dielectric layer 210 disposed in the YZ plane, the angled implantation process 212 has a tilt angle ranging from about 1 degree to about 60 degrees, such as from about 5 degrees to about 45 degrees. Furthermore, the substrate 101 is not rotated during the angled implantation process 212.

In some embodiments, the tilt angle A of the angled implantation is relatively small, such as less than about 15 degrees, for example from about 5 degrees to about 10 degrees. As a result, the portions of the dielectric layer 210 disposed in the XZ plane are implanted with the species from the bottom to the top. In other words, the species can reach the bottom of the portions of the dielectric layer disposed in the XZ plane with a relatively small tilt angle A. In such embodiments, more species may be implanted into the two or more S/D regions 146 exposed in a single opening 208 compared to the species implanted into the single S/D region 146 exposed in a single opening 208. The larger openings 208 leads to more species reaching the S/D regions 146 located at the bottom of the larger openings 208. The size of the opening 208 (i.e., the critical dimension of the opening 208 in the Y direction) determines the size of the subsequently formed conductive feature 230 (FIG. 13G) (i.e., the dimension of the conductive feature 230 in the Y direction). Thus, in some embodiments, there is a direct relationship between the size of the conductive feature 230 and the concentration of the species in the S/D regions 146 electrically connected to the conductive feature 230. For example, the concentration of the species in the two S/D regions 146 exposed in a single opening 208 is substantially greater than the concentration of the species in the single S/D region 146 exposed in a single opening 208.

FIG. 13D-1 illustrates concentration profiles of the species in two source/drain regions 146 of the semiconductor device structure 100, in accordance with some embodiments. In some embodiments, the concentration of the species in a first S/D region 146, which may be one of the two S/D regions 146 exposed in a single opening 208, has a first concentration profile 302, and the concentration of the species in a second S/D region 146, which may be the single S/D region 146 exposed in a single opening 208, has a concentration profile 304. As shown in FIG. 13D-1, the concentration of the species in the first S/D region 146 is substantially greater than the concentration of the species in the second S/D region 146. Both concentration profiles 302, 304 show a decrease in concentration of the species in a direction away from top surfaces of the first and second S/D regions 146.

In some embodiments, the tilt angle A of the angled implantation is relatively large, such as greater than about 30 degrees, for example from about 40 degrees to about 60 degrees. As a result, the portions of the dielectric layer 210 disposed in the XZ plane in larger openings 208 are implanted with the species from the bottom to the top, while the portions of the dielectric layer 210 disposed in the XZ plane in smaller openings 208 are implanted with the species in the top portion. In other words, the species cannot reach the bottom of the portions of the dielectric layer disposed in the XZ plane in smaller openings 208 with a relatively large tilt angle A. In such embodiments, more of the portions of the dielectric layer 210 disposed in the XZ plane are implanted with the species in larger openings 208, while only the top portions of the portions of the dielectric layer 210 disposed in the XZ plane are implanted with the species in smaller openings 208. For example, in the smallest opening 208, a top portion of the dielectric layer 210 in the Z direction disposed in the XZ plane are implanted with the species, and in the largest openings 208, the entire portions of the dielectric layer 210 in Z direction disposed in the XZ plane are implanted with the species. The length in the Z direction of the top portion of the dielectric layer 210 that is implanted with the species may increase as the size of the opening 208 increases.

The portions of the dielectric layer 210 implanted with the species (such as the top portion of entire portion of the portions of the dielectric layer 210 disposed in the XZ plane) may have a species concentration ranging from about 0.5 percent to about 10 percent, while the portions of the dielectric layer 210 not implanted with the species (such as the portions of the dielectric layer 210 disposed in the YZ plane and the bottom portion of the portions of the dielectric layer 210 disposed in the XZ plane) may have a species concentration ranging from about 0.01 percent to about 0.1 percent.

In some embodiments, after the angled implantation process, another implantation process is performed to implant a dopant in the S/D regions 146. The dopant may be any suitable dopant, such as Ge. The implantation process may not have a tilt angle and the substrate 101 may be rotated during the implantation process. Thus, the implantation process is different from the angled implantation process.

As shown in FIG. 13E, a clean process is performed on the semiconductor device structure 100. The clean process is to remove any residue etchant from the processes to form the openings 208 and to form the dielectric layer 210. In some embodiments, the portions of the dielectric layer 210 that are implanted with the species have a substantially greater etch rate than the portions of the dielectric layer 210 not implanted with the species during the clean process. As a result, the portions of the dielectric layer 210 implanted with the species are removed by the clean process. The clean process may be a wet etch process using diluted HF or a chemical oxide removal (COR) dry etch process. In some embodiments, the species in Ge and the clean process is a wet clean process using diluted HF. As a result, more than 1 nm of thickness of the portions of the dielectric layer 210 implanted with the species is removed by the clean process. As shown in FIG. 13E, in some embodiments, the portions of the dielectric layer 210 disposed in the XZ plane has a thickness T1, which is substantially less than the thickness of the portions of the dielectric layer 210 disposed in the XZ plane prior to the clean process. The thickness T1 may be substantially uniform as a result of the entire portion of the portions of the dielectric layer 210 in the Z direction disposed in the XZ plane is implanted with the species.

In some embodiments, the portions of the dielectric layer 210 disposed in the Z direction have non-uniform thickness after the clean process. As shown in FIG. 13F, the portions of the dielectric layer 210 disposed in the XZ plane in the smaller openings 208 include a top portion having the thickness T1 and a bottom portion having a thickness T2 substantially greater than the thickness T1. As described above, in some embodiments, the bottom portions of the portions of the dielectric layer 210 disposed in the XZ plane in the smaller openings 208 are not implanted with the species. As a result, the bottom portion of the portions of the dielectric layer 210 disposed in the XZ plane in the smaller openings 208 is not substantially affected by the clean process, while the thickness of the top portion of the portions of the dielectric layer 210 disposed in the XZ plane in the smaller openings 208 is reduced by the clean process. In some embodiments, because the entire portions of the dielectric layer 210 in the Z direction disposed in the XZ plane in the larger openings 208 are implanted with the species, the thickness of the portions of the dielectric layer 210 disposed in the XZ plane in the larger openings 208 is reduced to T1 by the clean process. As described above, the size of the conductive feature 230 is determined by the size of the opening 208. In some embodiments, there is a direction relationship between the size of the conductive feature 230 and a ratio of the portion of the dielectric layer 210 disposed in the XZ plane having the thickness T1 to the portion of the dielectric layer 210 disposed in the XZ plane having the thickness T2. For example, as shown in FIG. 13F, in the smallest opening 208, the portion of the dielectric layer 210 disposed in the XZ plane having the thickness T1 and the portion of the dielectric layer 210 disposed in the XZ plane having the thickness T2 may have a first ratio. In the opening 208 larger than the smallest opening 208 (middle opening 208), the portion of the dielectric layer 210 disposed in the XZ plane having the thickness T1 and the portion of the dielectric layer 210 disposed in the XZ plane having the thickness T2 may have a second ratio, which is greater than the first ratio due to the increased portion of the dielectric layer 210 disposed in the XZ plane having the thickness T1. In the largest opening 208 where no portion of the dielectric layer 210 disposed in the XZ plane has the thickness T2, the ratio of the portion of the dielectric layer 210 disposed in the XZ plane having the thickness T1 to the portion of the dielectric layer 210 disposed in the XZ plane having the thickness T2 would be infinite.

After the clean process, a silicide layer 214 is formed on each exposed S/D region 146, as shown in FIGS. 13E and 13F. The silicide layer 214 may include any suitable material, such as NiSi, TiSi, CoSi, RuSi, or wSi. The silicide layer 214 may be formed by any suitable process. In some embodiments, the silicide layers 214 is selectively formed on the S/D regions 146.

FIG. 13F-1 is a top view of the dielectric layer 210 of the semiconductor device structure, in accordance with some embodiments. After the clean process, the dielectric layer 210 includes a first portion 210a having the thickness T1 and a second portion 210b having the second thickness T2 substantially greater than the thickness T1. The first portion 210a may be the portion disposed in the XZ plane, while the second portion 210b may be the portion disposed in the YZ plane. The first portion 210a is connected to the second portion 210b. As described above, the first portion 210a is implanted with the species, while the second portion 210b is not. As a result, the clean process removes portions of the first portion 210a, while the second portion 210b is not substantially affected by the clean process. In some embodiments, the first portion 210a has a varied thickness along the Z direction. For example, a bottom portion of the first portion 210a has the thickness T2 substantially greater than the thickness T1 of a top portion of the first portion 210a. In some embodiments, the difference between the thicknesses T2 and T1 is greater than 1 nm.

As shown in FIG. 13G, the conductive features 230 are formed in the openings 208. The conductive features 230 may be electrically conductive and may include a material having one or more of Ru, Mo, Co, Ni, W, Ti, Ta, Cu, Al, TiN or TaN. The conductive features 230 may be formed by any suitable method, such as electro-chemical plating (ECP), or PVD. A planarization operation, such as a CMP method, is performed to remove portions of the conductive features 230 formed on the ILD layer 206. Referring back to FIG. 13F-1, in some embodiments, the dielectric layer 210 surrounds the conductive feature 230.

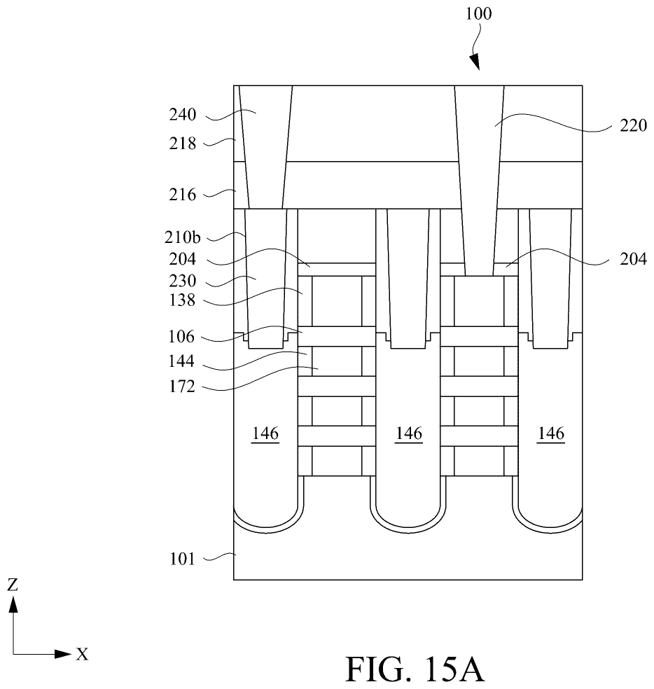

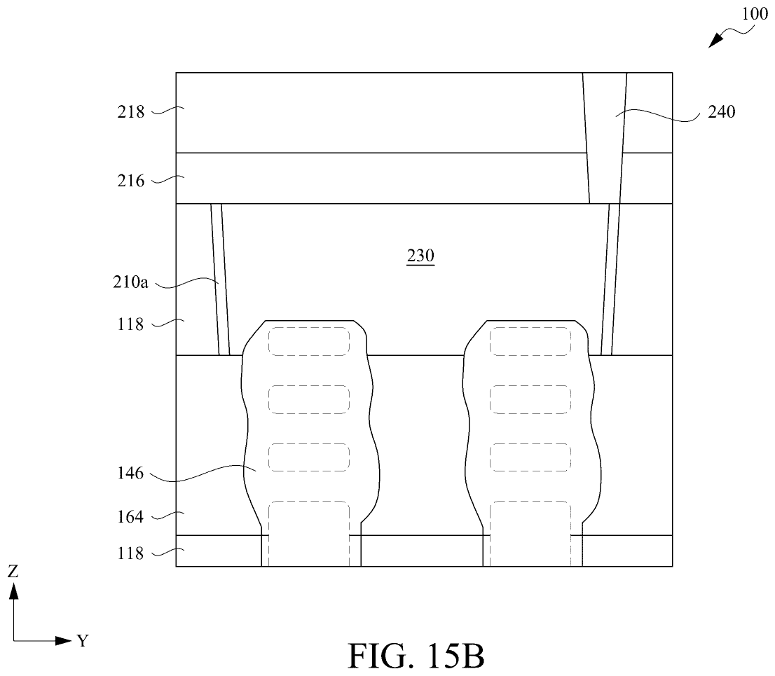

FIG. 14A-14B are cross-sectional side views of one of various stages of manufacturing the semiconductor device structure 100 taken along lines A-A, C-C of FIG. 6, respectively, in accordance with some embodiments. Components such as the gate dielectric layer 170, the silicide layer 214, and the CESL 162 are omitted for clarity. As shown in FIG. 14A, the conductive feature 230 and the gate electrode layer 172 are separated by the gate spacer 138 and the second portion 210b of the dielectric layer 210. The thickness of the second portion 210b of the dielectric layer 210 is not substantially affected by the clean process. As a result, electrical isolation between the conductive feature 230 and the gate electrode layer 172 is improved. As shown in FIG. 14B, the thickness of the first portion 210a of the dielectric layer 210 is reduced by the clean process. As a result, the process window for forming a conductive feature 240 (FIG. 15B) is enlarged.

FIG. 15A-15B are cross-sectional side views of one of various stages of manufacturing the semiconductor device structure 100 taken along lines A-A, C-C of FIG. 6, respectively, in accordance with some embodiments. Components such as the gate dielectric layer 170, the silicide layer 214, and the CESL 162 are omitted for clarity. As shown in FIG. 15A, an etch stop layer 216 is formed on the ILD layer 206, the dielectric layer 210, and the conductive features 230, and a dielectric layer 218 is formed on the etch stop layer 216. The etch stop layer 216 may include the same material as the etch stop layer 204, and the dielectric layer 218 may include the same material as the ILD layer 206. A conductive feature 220 is formed in the dielectric layer 218, the etch stop layer 216, the ILD layer 206, and the etch stop layer 204 to be electrically connected to the gate electrode layer 172. As shown in FIGS. 15A and 15B, the conductive feature 240 is formed in the dielectric layer 218 and the etch stop layer 216, and the conductive feature 240 is electrically connected to the conductive feature 230. In some embodiments, the conductive feature 240 is in direct contact with the conductive feature 230. As shown in FIG. 15B, due to the reduced thickness of the first portion 210a of the dielectric layer 210, the process window for forming the conductive feature 240 is enlarged. Furthermore, in some embodiments, the conductive feature 240 is in contact with both the conductive feature 230 and the first portion 210a of the dielectric layer 210, as shown in FIG. 15B. Due to the smaller thickness T1 of the first portion 210a of the dielectric layer 210, the contact resistance of the conductive feature 240 is reduced.

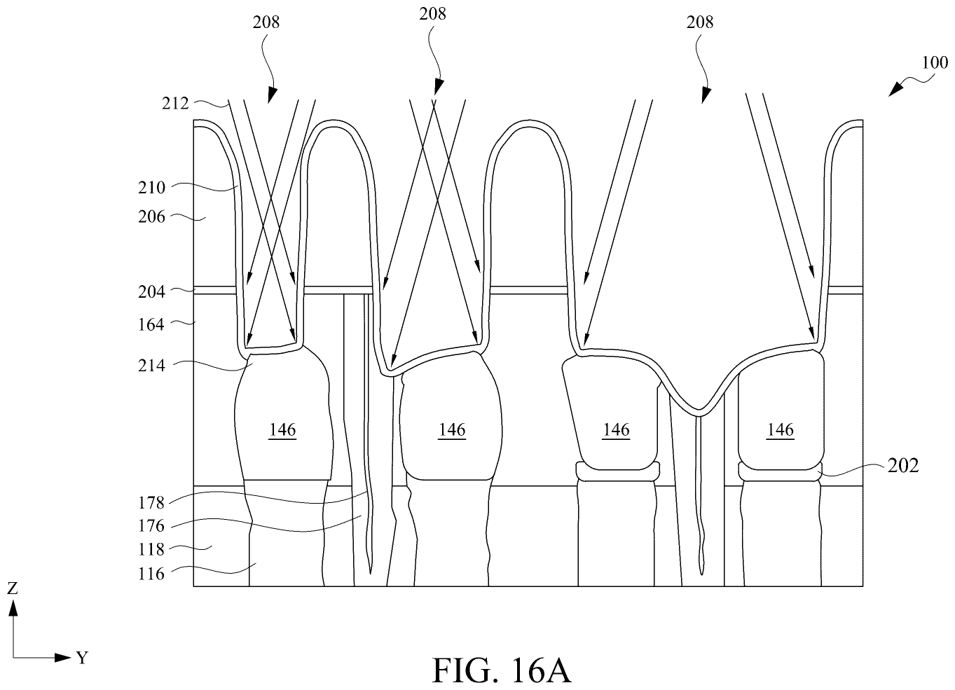

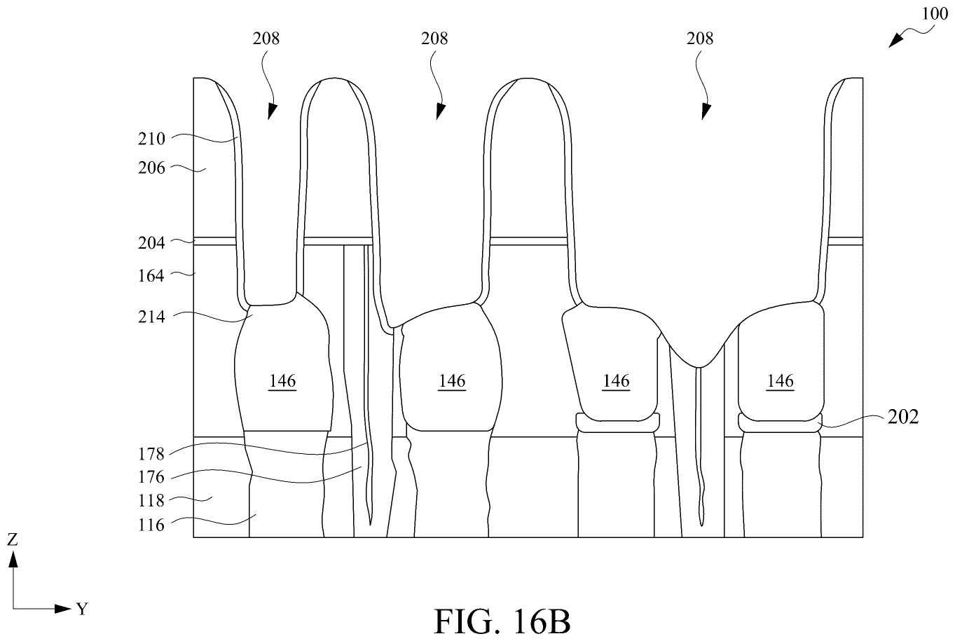

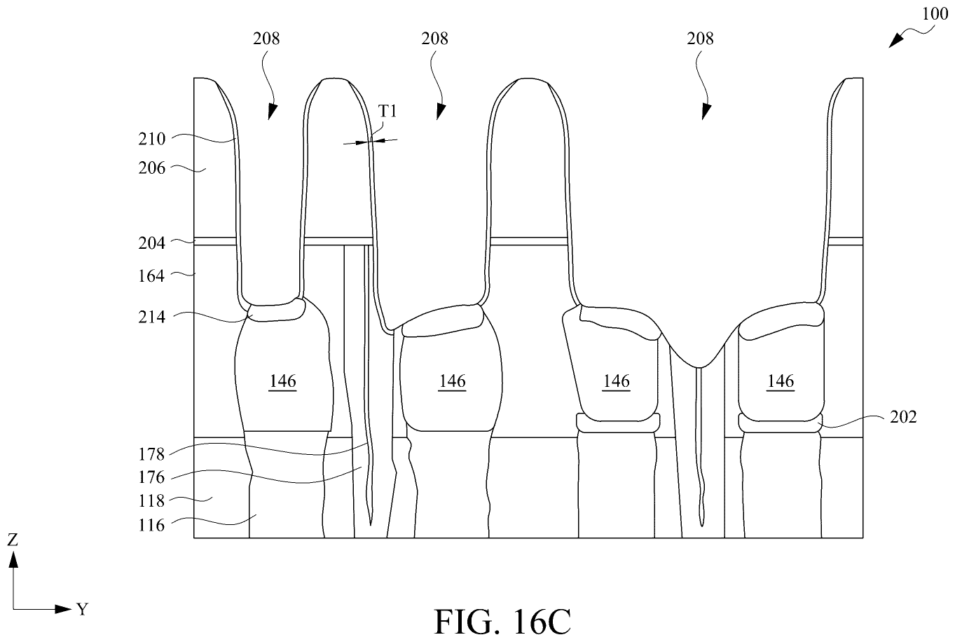

FIGS. 16A-16C are cross-sectional side views of various stages of manufacturing the semiconductor device structure 100 taken along line C-C of FIG. 6, in accordance with alternative embodiments. In some embodiments, the angled implantation process 212 is performed after the deposition of the dielectric layer 210 but prior to the anisotropic etch process to remove the horizontal portions of the dielectric layer 210. The angled implantation process implants the species in the portions of the dielectric layer 210 disposed in the XZ plane. In such embodiments, the species from the angled implantation process 212 may not be implanted into the S/D regions 146. Similar to the processes described in FIGS. 13D, the top portion or the entire portion of the dielectric layer 210 disposed in the XZ plane (or the first portion 210a) may be implanted with the species, depending on the tilt angle A (FIG. 13D).

As shown in FIG. 16B, the anisotropic etch process is performed to remove the horizontal portions of the dielectric layer 210. The species in the portions of the dielectric layer 210 does not substantially affect the result of the anisotropic etch process. In other words, at the end of the anisotropic etch process, the thickness of the dielectric layer 210 may be substantially uniform.

As shown in FIG. 16C, the implantation process, the clean process, and the process to form the silicide layers 214 are performed. Similar to the processes described in FIGS. 13E, 13F, and 13F-1, the thickness of the dielectric layer 210 varies after the clean process. Processes described in FIGS. 14A, 14B, 15A, 15B are then performed. By performing the angled implantation process 212 prior to the anisotropic etch process, the species are not implanted in the S/D regions 146.

Embodiments of the present disclosure provide a semiconductor device structure 100 including a dielectric layer 210 having a first portion 210a disposed in a first plane and a second portion 210b disposed in a second plane substantially perpendicular to the first plane. The first portion 210a has a first thickness T1, and the second portion 210b has a second thickness T2 substantially greater than the first thickness T1. Some embodiments may achieve advantages. For example, with larger thickness T2, the electrical isolation between the conductive feature 230 and the gate electrode layer 172 is improved. With the smaller thickness T1, the process window for forming a conductive feature 240 is enlarged.

An embodiment is a semiconductor device structure. The structure includes a source/drain region disposed over a substrate, an interlayer dielectric layer disposed over the source/drain region, a first conductive feature disposed over the source/drain region, a gate electrode layer disposed over the substrate, and a dielectric layer surrounding the first conductive feature. The dielectric layer includes a first portion disposed between the interlayer dielectric layer and the first conductive feature and a second portion disposed between the first conductive feature and the gate electrode layer, at least a portion of the first portion has a first thickness, and the second portion has a second thickness substantially greater than the first thickness.

Another embodiment is a semiconductor device structure. The structure includes first and second source/drain regions disposed over a substrate, each of the first and second source/drain regions comprises a species, the first source/drain region has a first concentration of the species, and the second source/drain region has a second concentration of the species substantially less than the first concentration of species. The structure further includes a first conductive feature disposed over the first source/drain region, and the first conductive feature has a first size. The structure further includes a second conductive feature disposed over the second source/drain region, and the second conductive feature has a second size substantially smaller than the first size.

A further embodiment is a method. The method includes forming a fin structure from a substrate, recessing a portion of the fin structure to expose a substrate portion, forming a source/drain region over the substrate portion, forming a gate electrode layer over the substrate, depositing an interlayer dielectric layer over the source/drain region, forming an opening in the interlayer dielectric layer to expose the source/drain region, and depositing a dielectric layer in the opening. The dielectric layer includes a first portion disposed in a first plane and a second portion disposed in a second plane substantially perpendicular to the first plane. The method further includes performing an angled implantation process to implant a species into the dielectric layer, and a species concentration in the first portion of the dielectric layer is substantially greater than a species concentration of the second portion of the dielectric layer. The method further includes performing a clean process to remove a portion of the first portion of the dielectric layer and filling the opening with a conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain region disposed over a substrate;
an interlayer dielectric layer disposed over the source/drain region;
a first conductive feature disposed over the source/drain region;
a gate electrode layer disposed over the substrate; and
a dielectric layer surrounding the first conductive feature, wherein the dielectric layer comprises a first portion disposed between the interlayer dielectric layer and the first conductive feature and a second portion disposed between the first conductive feature and the gate electrode layer, wherein at least a portion of the first portion has a first thickness, and the second portion has a second thickness substantially greater than the first thickness.

2. The semiconductor device structure of claim 1, wherein a difference between the first thickness and the second thickness is greater than about 1 nm.

3. The semiconductor device structure of claim 1, wherein the dielectric layer comprises SiO₂, SiOC, SiOCN, or SiN.

4. The semiconductor device structure of claim 1, further comprising a silicide layer disposed between the source/drain region and the first conductive feature.

5. The semiconductor device structure of claim 4, further comprising a second conductive feature in contact with the first conductive feature and the first portion of the dielectric layer.

6. The semiconductor device structure of claim 1, further comprising a plurality of semiconductor layers, wherein the gate electrode layer surrounds at least a portion of each of the plurality of semiconductor layers.

7. The semiconductor device structure of claim 1, wherein the first portion comprises a top portion having the first thickness and a bottom portion having a third thickness substantially greater than the first thickness.

8. The semiconductor device structure of claim 7, wherein the third thickness is substantially the same as the second thickness.

9. A semiconductor device structure, comprising:
first and second source/drain regions disposed over a substrate, wherein each of the first and second source/drain regions comprises a species, the first source/drain region has a first concentration of the species, and the second source/drain region has a second concentration of the species substantially less than the first concentration of species;
a first conductive feature disposed over the first source/drain region, wherein the first conductive feature has a first size; and
a second conductive feature disposed over the second source/drain region, wherein the second conductive feature has a second size substantially smaller than the first size.

10. The semiconductor device structure of claim 9, further comprising a dielectric layer surrounding the first conductive feature.

11. The semiconductor device structure of claim 10, wherein the dielectric layer comprises a first portion and a second portion, wherein the first portion is connected to and substantially perpendicular to the second portion.

12. The semiconductor device structure of claim 11, wherein the first portion has a first thickness, and the second portion has a second thickness substantially greater than the first thickness.

13. The semiconductor device structure of claim 11, wherein the first portion comprises a top portion having a third thickness and a bottom portion having a fourth thickness substantially greater than the third thickness.

14. The semiconductor device structure of claim 9, wherein the species comprises Xe or Ar.

15. A method, comprising:
forming a fin structure from a substrate;
recessing a portion of the fin structure to expose a substrate portion;
forming a source/drain region over the substrate portion;
forming a gate electrode layer over the substrate;
depositing an interlayer dielectric layer over the source/drain region;
forming an opening in the interlayer dielectric layer to expose the source/drain region;
depositing a dielectric layer in the opening, wherein the dielectric layer comprises a first portion disposed in a first plane and a second portion disposed in a second plane substantially perpendicular to the first plane;
performing an angled implantation process to implant a species into the dielectric layer, wherein a species concentration in the first portion of the dielectric layer is substantially greater than a species concentration of the second portion of the dielectric layer;
performing a clean process to remove a portion of the first portion of the dielectric layer; and
filling the opening with a conductive feature.

16. The method of claim 15, further comprising removing horizontal portions of the dielectric layer prior to performing the angled implantation process.

17. The method of claim 15, further comprising removing horizontal portions of the dielectric layer after performing the angled implantation process, wherein the clean process is performed after the removing the horizontal portions of the dielectric layer.

18. The method of claim 15, wherein the clean process is a wet clean process using diluted HF.

19. The method of claim 15, wherein the angled implantation process has a tilt angle ranging from about 1 degree to about 60 degrees.

20. The method of claim 19, wherein the species comprises Ge, Xe, Ar, or Si.
